(19) United States
(12) Patent Application Publication
(10) Pub. No.: US 2023/0317823 A1
(43) Pub. Date: Oct. 5, 2023

(54) APPARATUSES INCLUDING LOW-K SPACERS AND METHODS FOR FORMING SAME

(71) Applicant: Micron Technology, Inc., Boise, ID (US)

(72) Inventors: Kehan Zhang, Hiroshima (JP); Yoshikazu Moriwaki, HIroshima (JP)

(73) Assignee: Micron Technology, Inc., Boise, ID (US)

(21) Appl. No.: 17/711,909

(22) Filed: Apr. 1, 2022

(51) Int. Cl. H01L 29/66; H01L 29/78

(52) U.S. Cl. CPC H01L 29/6656; H01L 29/6653; H01L 29/7833

(57) ABSTRACT

A semiconductor structure includes a first sidewall spacer on sidewalls of a first device structure on a surface of a substrate and a second sidewall spacer on sidewalls of a second device structure on the surface of the substrate. The first sidewall spacer includes a first liner layer on sidewalls of the first device structure, a first oxide spacer on the first liner layer and on the surface of the substrate, and a first etch stop layer on the first oxide spacer. The second sidewall spacer includes a second liner layer on sidewalls of the second device structure, an inner oxide spacer on the second liner layer and on the surface of the substrate, a second etch stop layer on the inner oxide layer, and an outer oxide spacer on the second etch stop layer.

### BACKGROUND

As semiconductor devices become highly integrated, parasitic capacitance across the device becomes a greater contributor to device performance. For example, in a dynamic random access memory (DRAM) device, capacitive coupling through a spacer between a gate stack and a metal contact causes cross talk and propagation delay, leading to degraded tWR (write recovery time) and other faulty behaviors. This issue of parasitic capacitance is aggravated by the common use of spacers formed of silicon nitride that has a relatively large dielectric constant (k˜7.0).

Furthermore, such devices often include two or more structures that require spacers of different thickness depending on device reliability and performance requirements. For example, in a DRAM device, periphery gate stacks require thicker spacers than sense amplifier gate stacks.

Therefore, spacers having a low dielectric constant and well-controlled widths, and methods for forming such spacers may be desirable.

### BRIEF DESCRIPTION OF THE SEVERAL VIEWS OF THE DRAWINGS

FIG. 1A is a plan view of a memory die of a semiconductor memory device according to an embodiment of the disclosure.

FIG. 1B is a cross-sectional view of a portion of the memory die depicted in FIG. 1A.

FIG. 2A is a cross-sectional view of a portion of a semiconductor structure.

FIG. 2B is a cross-sectional view of a portion of a semiconductor structure according to an embodiment of the disclosure.

FIG. 3 is a process flow diagram of a method of forming a semiconductor structure according to an embodiment of the disclosure.

FIGS. 4A, 4B, 4C, 4D, and 4E are cross-sectional views of a portion of the semiconductor structure corresponding to various states of the method depicted in FIG. 3.

### DETAILED DESCRIPTION

The following description of certain embodiments is merely exemplary in nature and is in no way intended to limit the scope of the disclosure or its applications or uses. In the following detailed description of embodiments of the present systems and methods, reference is made to the accompanying drawings which form a part hereof, and which are shown by way of illustration specific embodiments in which the described systems and methods may be practiced. These embodiments are described in sufficient detail to enable those skilled in the art to practice presently disclosed systems and methods, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with ordinary skill in the art so as not to obscure the description of embodiments of the disclosure. The following detailed description is therefore not to be taken in a limiting sense, and the scope of the disclosure is defined only by the appended claims.

The embodiments described herein provide spacers that can be used in an integrated semiconductor device, such as a semiconductor memory device. The spacers have a reduced dielectric constant compared to the conventional silicon nitride spacers by partially replacing silicon nitride material (dielectric constant k˜7.0) with silicon-containing oxide material, such as silicon dioxide (dielectric constant k˜3.9). Furthermore, the apparatuses and methods described herein provide spacers having different thickness.

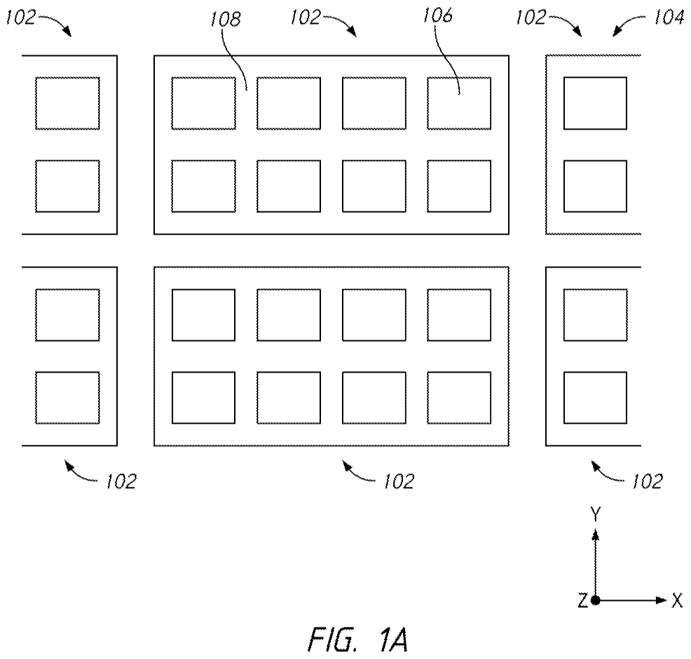

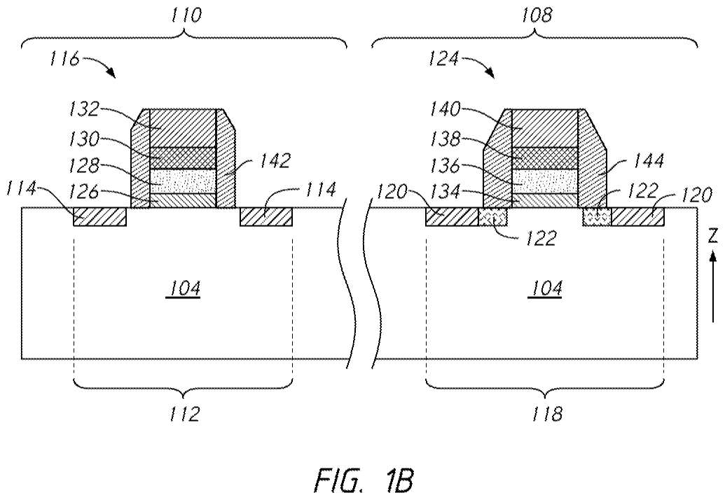

FIG. 1A is a plan view of a memory die 102 of a semiconductor memory device according to an embodiment of the disclosure. In the fabrication process, memory dies 102 (e.g., 200 memory dies 102) are arranged in a matrix form on a surface of a substrate 104 and the substrate 104 is subsequently diced to separate individual memory dies 102. Each memory die 102 includes an array of memory cell regions 106 and periphery regions 108. Each memory cell region 106 includes a sense amplifier region and abuts a periphery region 108. Each periphery region 108 may include row drivers, row decoders, and row address latches, each of which uses one or more transistor structures. Each sense amplifier region may include sense amplifiers, column decoders, and column address latches, each of which includes one or more transistor structures.

FIG. 1C is a cross-sectional view of a portion of the memory die 102 depicted in FIGS. 1A, including a portion of the memory cell region 106, a portion of a sense amplifier region 110 and a portion of the periphery region 108.

The sense amplifier region 110 includes one or more transistor structures 112, each having diffusion layers 114 as source/drain electrodes and a gate stack 116 as a gate electrode.

The periphery region 108 includes one or more transistor structures 118, each including diffusion layers 120 that are adjacent to lightly-doped regions 122, as source/drain electrodes, and a gate stack 124 between the lightly-doped regions 122, as a gate electrode.

The gate stack 116 includes a gate dielectric 126 on a surface of the substrate 104, a gate layer 128 on the gate dielectric 126, a metal layer 130 on the gate layer 128, and a cap layer 132 on the metal layer 130. The gate stack 124 also includes a gate dielectric 134 on the surface of the substrate 104, a gate layer 136 on the gate dielectric 134, a metal layer 138 on the gate layer 136, and a cap layer 140 on the metal layer 138.

The gate dielectrics 126 and 134 may include a stack of a thin silicon dioxide (SiO₂) interfacial layer (IL), and a dielectric layer of a dielectric material having a dielectric constant greater than that of silicon dioxide (SiO₂) (dielectric constant k˜3.9). Examples of such dielectric material include hafnium oxide (HfO₂), zirconium dioxide (ZrO₂), aluminum oxide (Al₂O₃), titanium oxide (TiO₂), lanthanum oxide (La₂O₃), strontium titanate (SrTiO₃), lanthanum aluminate (LaAlO₃), yttrium oxide (Y₂O₃), and combination thereof. A metal gate layer includes titanium (Ti), zirconium (Zr), hafnium (Hf), V, Nb, tantalum (Ta), or alloys thereof, such as titanium nitride (TiN) or tantalum nitride (TaN). The gate layers 128 and 136 each include a conductively-doped silicon-containing material, such as, for example, conductively-doped polycrystalline silicon or conductively-doped amorphous silicon. The metal layers 130 and 138 include a low resistive metal, such as tungsten (W). The cap layers 132 and 140 include an electrically insulating material, such as, for example, silicon nitride (Si₃N₄).

The gate stack 116 further includes a sidewall spacer 142 on sidewalls of the gate stack 116. The gate stack 124 further includes a sidewall spacer 144 on sidewalls of the gate stack 124. The sidewall spacers 142 and 144 include any suitable insulating material, including, one or both of silicon nitride and silicon dioxide. In some embodiments of the disclosure, the sidewall spacer 142 has a thickness of between about 10 nm and about 20 nm, and the sidewall spacer 144 each have a thickness of between about 20 nm and about 30 nm.

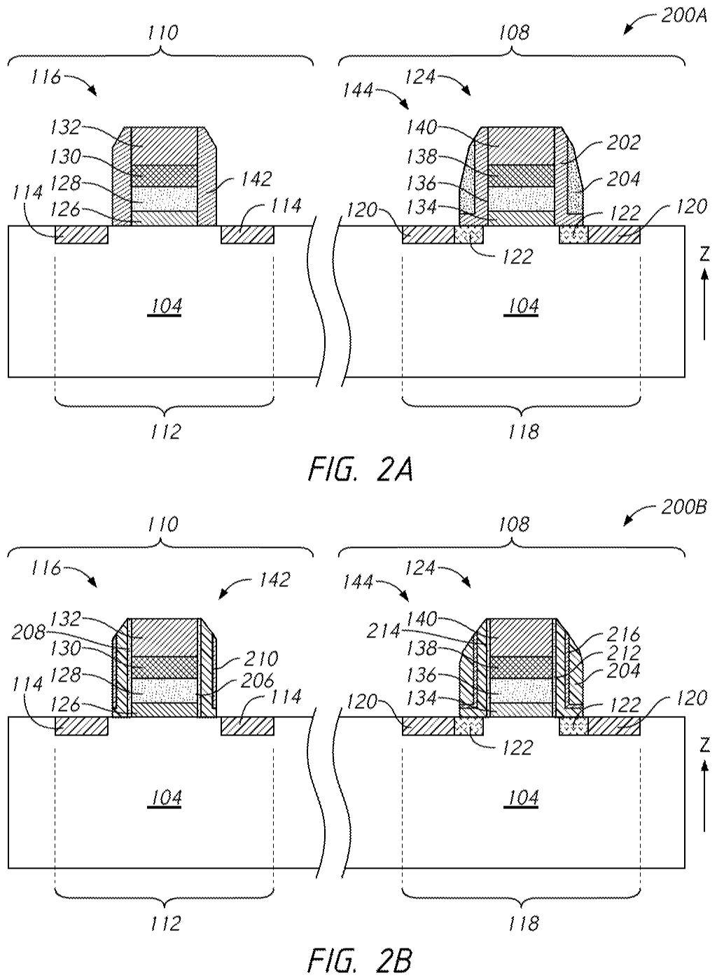

FIG. 2A is a cross-sectional view of portions of the transistor structure 112 included in the sense amplifier region 110 and the transistor structure 118 included in the periphery region 108.

Conventionally, the sidewall spacer 142 of the transistor structure 112 includes silicon-containing nitride material, such as silicon nitride, that has an etch selectivity with respect to silicon-containing oxide material, such as silicon dioxide. The sidewall spacer 144 of the transistor structure 118 is thicker than the sidewall spacer 142 of the transistor structure 112. The thicker sidewall spacer 144 includes a nitride spacer 202 and an additional outer oxide spacer 204. The nitride spacer 202 is on sidewalls of the transistor structure 118 and on the surface of the substrate 104. The outer oxide spacer 204 is on the nitride spacer 202 (i.e., outside of a portion of the nitride spacer 202 on the sidewalls of the transistor structure 118 and over a portion of the nitride spacer 202 on the surface of the substrate 104). The nitride spacer 202 includes silicon-containing nitride material, such as silicon nitride. The outer oxide spacer 204 includes silicon-containing oxide material.

FIG. 2B is a cross-sectional view of portions of the transistor structure 112 included in the sense amplifier region 110 and the transistor structure 118 included in the periphery region 108 according to an embodiment of the disclosure. As depicted in FIG. 2B, the sidewall spacer 142 that includes silicon-containing nitride material in FIG. 2A is partially replaced by silicon-containing oxide material, and the nitride spacer 202 of the sidewall spacer 144 of the transistor structure 118 in FIG. 2A is also partially replaced by silicon-containing oxide material. Since the dielectric constant k of silicon-containing oxide material (e.g., k˜3.9 for silicon dioxide SiO₂) is lower than that of silicon-containing nitride material (e.g., k˜7.0 for silicon nitride Si₃N₄), the capacitance of the sidewall spacer 142 is relatively reduced by the replacement of silicon-containing nitride material with silicon-containing oxide material. The capacitance of the sidewall spacer 144 is also reduced by the replacement of silicon-containing nitride material with silicon-containing oxide material.

As shown in FIG. 2B, the sidewall spacer 142 of the transistor structure 112 includes an inner liner layer 206 on the sidewalls of the transistor structure 112, an oxide spacer 208 on the inner liner layer 206 and on the surface of the substrate 104, and an outer liner layer 210 on the oxide spacer 208 (i.e., outside a portion of the oxide spacer 208 on the sidewalls of the transistor structure 112 and over a portion of the oxide spacer 208 on the surface of the substrate 104). The sidewall spacer 144 of the transistor structure 118 includes an inner liner layer 212 on the sidewalls of the transistor structure 118, an inner oxide spacer 214 on the inner liner layer 212 and on the surface of the substrate 104, an outer liner layer 216 on the inner oxide spacer 214 (i.e., outside a portion of the inner oxide spacer 214 on the sidewalls of the transistor structure 118 and over a portion of the inner oxide spacer 214 on the surface of the substrate 104), and the outer oxide spacer 204 on the outer liner layer 216 (i.e., outside a portion of the outer liner layer 216 on the sidewalls of the transistor structure 118 and over a portion of the outer liner layer 216 over the surface of the substrate 104). In some embodiments, the outer liner layer 210 and the outer liner layer 216 may provide etch stop layers. The oxide spacer 208, the inner oxide spacer 214, and the outer oxide spacer 204 include silicon-containing oxide material, such as silicon dioxide (SiO₂, dielectric constant k˜3.9), silicon oxycarbide (SiOC), organosilicate (SiCOH), and tetraethyl orthosilicate (TEOS, Si(OC₂H₅)₄). The inner liner layer 206, the inner liner layer 212, the outer liner layer 210 and the outer liner layer 216 include silicon-containing nitride material that has a high etch selectivity to silicon-containing oxide material. Examples of the silicon-containing nitride material include silicon nitride (Si₃N₄, dielectric constant k˜7.0), silicon oxycarbonnitride (SiOCN), and silicoboron carbonitride (SiBCN). In some embodiments, the outer liner layer 210 and the outer liner layer 216 include polycrystalline silicon that also has a high etch selectivity to silicon-containing oxide material. The outer liner layer 210 and the outer liner layer 216 that include polycrystalline silicon are oxidized in the subsequent oxide deposition process and exhibit a lower dielectric constant than silicon-containing nitride material. Thus, the parasitic capacitance through the sidewall spacer 142 and the sidewall spacer 144 having the outer liner layer 210 and the outer liner layer 216 formed of polycrystalline silicon can be reduced even further. In some examples, the sidewall spacer 142 has a thickness of between about 10 nm and about 20 nm, and the sidewall spacer 144 has a thickness of between about 20 nm and about 30 nm. The inner liner layer 206 has a thickness of between about 5 nm and about 8 nm. The oxide spacer 208 has a thickness of between about 6 nm and 8 nm. The outer liner layer 210 has a thickness of between about 1 nm and about 5 nm. The outer liner layer 216 has a thickness of between about 1 nm and about 5 nm. The inner oxide spacer 214 has a thickness of between about 6 nm and about 8 nm. The outer oxide spacer 204 has a thickness of between about 8 nm and about 10 nm. The thicknesses previously described are example thicknesses for various embodiments of the disclosure. However, embodiments of the disclosure are not limited to these specific thicknesses and dimensions. Other embodiments may have different thicknesses and dimensions without departing from the scope of the disclosure.

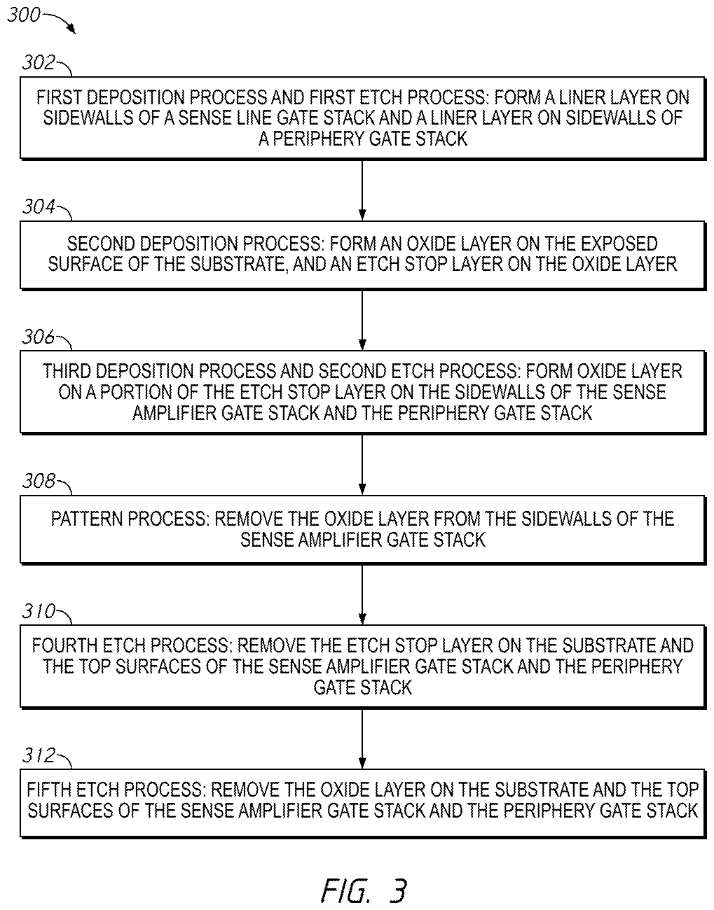

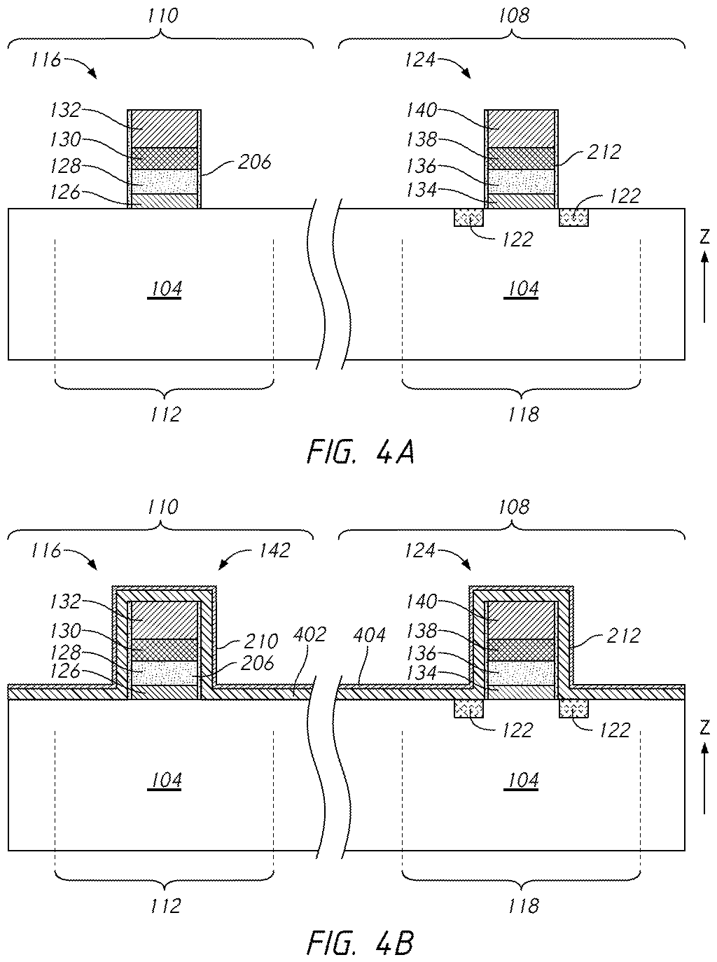

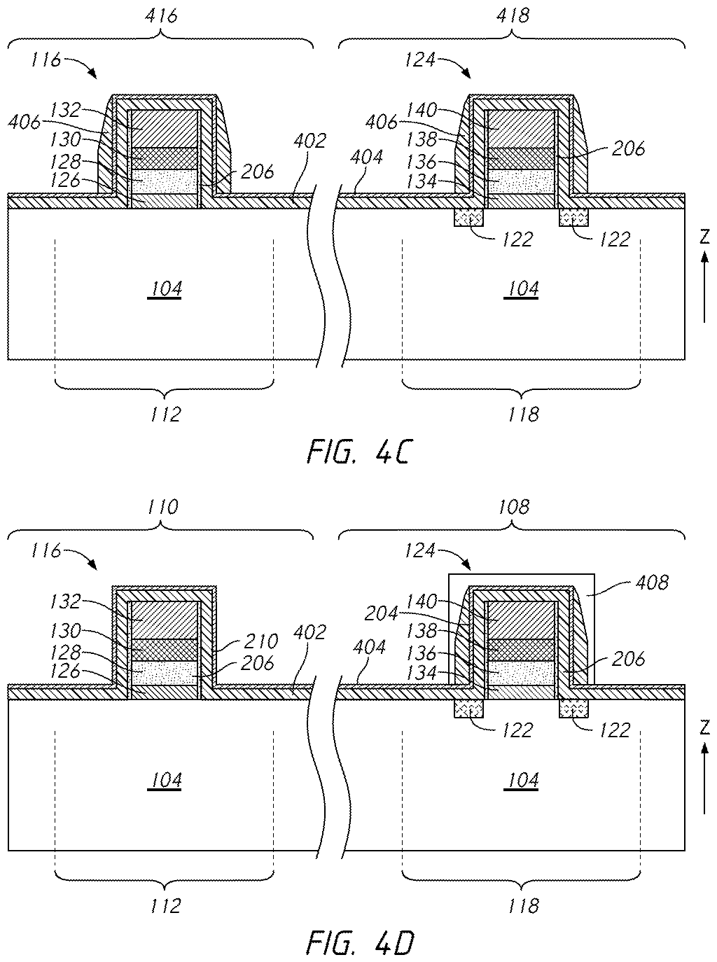

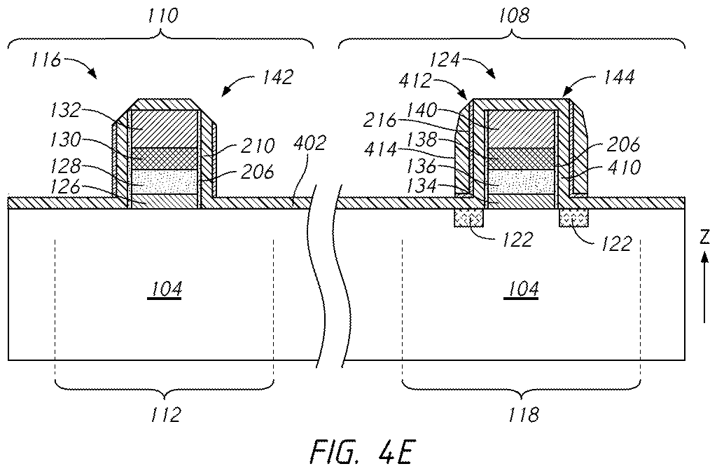

FIG. 3 is a process flow diagram of a method 300 of forming a semiconductor structure 200B including sidewall spacers, such as the sidewall spacers 142 and 144 as shown in FIG. 2B, according to certain embodiments. FIGS. 4A, 4B, 4C, 4D, and 4E are cross-sectional views of a portion of the semiconductor structure 200B corresponding to various states of the method 300. It should be understood that FIGS. 4A, 4B, 4C, 4D, and 4E illustrate only partial schematic views of the semiconductor structure 200B, and the semiconductor structure 200B may contain any number of transistor structures and additional materials having aspects as illustrated in the figures. It should also be noted although the method steps illustrated in FIG. 3 are described sequentially, other process sequences that include one or more method steps that have been omitted and/or added, and/or has been rearranged in another desirable order, fall within the scope of the embodiments of the present disclosure.

In the example described herein, the method 300 is applied for forming sidewall spacers of different thickness for a transistor structure 112 and a transistor structure 118 that are formed on a surface of a substrate 104. However, the method 300 can be applied to other semiconductor device structures that require sidewall spacers of different thickness.

The method 300 begins with block 302, in which a first deposition process and a first etch process are performed to form an inner liner layer 206 on sidewalls of the gate stack 116 of the transistor structure 112 in the sense amplifier region 110 and an inner liner layer 212 on sidewalls of the gate stack 124 of the transistor structure 118 in the periphery region 108, as shown in FIG. 4A. The inner liner layer 206 and the inner liner layer 212 include silicon-containing nitride material that has a high etch selectivity to silicon-containing oxide material. Examples of the silicon-containing nitride material include silicon nitride (Si₃N₄, dielectric constant k˜7.0), silicon oxycarbonnitride (SiOCN), and silicoboron carbonitride (SiBCN). In the first deposition process, a nitride layer including the silicon-containing nitride material is deposited conformally on the exposed surface of the substrate 104 (i.e., a surface of the substrate 104, and top surfaces and sidewalls of the gate stack 116 and the gate stack 124) using any appropriate deposition process, such as chemical vapor deposition (CVD), sputtering, spin-on, physical vapor deposition (PVD), or the like. In the first etch process, a portion of the deposited nitride layer on the surface of the substrate 104 and the top surfaces of the gate stack 116 and the gate stack 124 is removed by a dry etch process, such as reactive-ion etching, leaving the nitride layer on the sidewalls of the gate stack 116 and the gate stack 124 to form the inner liner layers 206 and 212. In some embodiments of the disclosure, the inner liner layer 206 and 212 may have a thickness of between about 1 nm and about 5 nm. Subsequently, lightly-doped regions 122 may be formed within the substrate 104 outside of the inner liner layer 212 by ion implantation.

In block 304, a second deposition process is performed to form an oxide layer 402 on the exposed surface of the substrate 104 (i.e., the surface of the substrate 104, the top surfaces of the gate stack 116 and the gate stack 124, the inner liner layer 206, and the inner liner layer 212), and further form an outer liner layer 404 (referenced in FIG. 3 as an etch stop layer) on the oxide layer 402, as shown in FIG. 4B. The oxide layer 402 includes silicon-containing oxide material, such as silicon dioxide, silicon oxycarbide (SiOC), organosilicate (SiCOH), and tetraethyl orthosilicate (TEOS, Si(OC₂H₅)₄). In some embodiments, the outer liner layer 404 includes silicon-containing nitride material that has a high etch selectivity to silicon-containing oxide material. Examples of the silicon-containing nitride material include silicon nitride (Si₃N₄, dielectric constant k˜7.0), silicon oxycarbonnitride (SiOCN, k˜4.5), and silicoboron carbonitride (SiBCN). In some other embodiments, the outer liner layer 404 includes polycrystalline silicon. The outer liner layer 404 including polycrystalline silicon is oxidized in the subsequent oxide deposition process and exhibits a lower dielectric constant than an outer liner layer including silicon-containing nitride material. The second deposition process is performed using any appropriate deposition process, such as chemical vapor deposition (CVD), sputtering, spin-on, physical vapor deposition (PVD), or the like.

In block 306, a third deposition process and a second etch process are performed to form an oxide layer 406 on a portion of the outer liner layer 404 on the sidewalls of the gate stack 116 and the gate stack 124, as shown in FIG. 4C. The oxide layer 406 includes silicon-containing oxide material, such as silicon dioxide, silicon oxycarbide (SiOC), organosilicate (SiCOH), and tetraethyl orthosilicate (TEOS, Si(OC₂H₅)₄).

In the third deposition process, an oxide layer including the silicon-containing oxide material is deposited conformally on the outer liner layer 404 on the substrate 104, and the top surfaces and the sidewalls of the gate stack 116 and the gate stack 124. The silicon containing oxide material is deposited using any appropriate deposition process, such as chemical vapor deposition (CVD), sputtering, spin-on, physical vapor deposition (PVD), or the like. In the second etch process, a portion of the deposited oxide layer on the surface of the substrate 104 and top surfaces of the gate stack 116 and the gate stack 124 is removed down to the outer liner layer 404 by a dry etch process, such as reactive-ion etching. The oxide layer remaining on the sidewalls of the gate stack 116 and the gate stack 124 are the oxide layer 406. In some embodiments of the disclosure, the oxide layer 406 may have a thickness of between about 8 nm and about 10 nm.

In block 308, a pattern process is performed to remove the oxide layer 406 from the sidewalls of the gate stack 116, as shown in FIG. 4D. The pattern process may include a lithography process to form a patterned photoresist 408 that covers the gate stack 116. The pattern process is followed by a third etch process to remove the oxide layer 406 only from the sidewalls of the gate stack 116 and leave the oxide layer 406 on the sidewalls of the gate stack 124 to be the outer oxide spacer 204. Subsequently, the photoresist 408 is stripped by an appropriate wet etch process.

In block 310, a fourth etch process is performed to remove the outer liner layer 404 on the substrate 104 and the top surfaces of the gate stack 116 and the gate stack 124, as shown in FIG. 4E. The outer liner layer 404 remains on the sidewalls of the transistor structure 112 and the transistor structure 118 to be the outer liner layer 210 of the sidewall spacer 142 and the outer liner layer 216 of the sidewall spacer 144. The fourth etch process is performed by a dry etch process, such as reactive-ion etching.

In block 312, a fifth etch process is performed to remove the oxide layer 402 on the substrate 104 and the top surfaces of the gate stack 116 and the gate stack 124. The oxide layer 402 remains on the sidewalls of the gate stack 116 and the gate stack 124 to be the oxide spacer 208 of the sidewall spacer 142 and the inner oxide spacer 214 of the sidewall spacer 144. Subsequently, the diffusion layers 114 may be formed within the substrate 104 outside of the sidewall spacers 142 in the sense amplifier region 110, and the diffusion layers 120 may be formed within the substrate outside of the sidewall spacers 144 in the periphery region 108, by ion implantation. The resulting structure is shown in FIG. 2B.

The embodiments described herein provide spacers that have reduced dielectric constant compared to the conventional silicon nitride spacers and methods for forming the same. The spacers according to the embodiments described herein have a reduced dielectric constant by partial replacement of silicon nitride material (dielectric constant k˜7.0) with silicon-containing oxide material, such as silicon dioxide (dielectric constant k˜3.9), and thus provide a reduced parasitic capacitance within an integrated semiconductor device. Furthermore, the methods described herein allow formation of spacers of different thickness. As a result, spacers having a low dielectric constant and well-controlled width can be fabricated.

From the foregoing it will be appreciated that, although specific embodiments of the disclosure have been described herein for purposes of illustration, various modifications may be made without deviating from the spirit and scope of the disclosure. Accordingly, the scope of the disclosure should not be limited any of the specific embodiments described herein.

What is claimed is:

1. A semiconductor structure, comprising:
a first sidewall spacer on sidewalls of a first device structure on a surface of a substrate, the first sidewall spacer comprising:
a first inner liner layer on sidewalls of the first device structure;
a first oxide spacer on the first inner liner layer and on the surface of the substrate; and
a first outer liner layer on the first oxide spacer; and
a second sidewall spacer on sidewalls of a second device structure on the surface of the substrate, the second sidewall spacer comprising:
a second inner liner layer on sidewalls of the second device structure;
an inner oxide spacer on the second inner liner layer and on the surface of the substrate;
a second outer liner layer on the inner oxide layer; and
an outer oxide spacer on the second outer liner layer,
wherein the first inner liner layer and the second inner liner layer comprise silicon-containing nitride material, and the first oxide spacer, the inner oxide spacer, and the outer oxide spacer comprise silicon-containing oxide material.

2. The semiconductor structure of claim 1, wherein
the first outer liner layer and the second outer liner layer comprise silicon-containing nitride material.

3. The semiconductor structure of claim 1, wherein
the first outer liner layer and the second outer liner layer comprise polycrystalline silicon.

4. The semiconductor structure of claim 1, wherein
the first sidewall spacer has a thickness of between 10 nm and 20 nm, and
the second sidewall spacer has a thickness of between 20 nm and 30 nm.

5. The semiconductor structure of claim 4, wherein
the first oxide spacer has a thickness of between 6 nm and 8 nm,
the inner oxide spacer has a thickness of between 6 nm and 8 nm, and
the outer oxide spacer has a thickness of between 8 nm and 10 nm.

6. The semiconductor structure of claim 4, wherein
the first inner liner layer and the second inner liner layer each have a thickness of between 5 nm and 8 nm.

7. The semiconductor structure of claim 4, wherein
the first outer liner layer and the second outer liner layer each have a thickness of between 1 nm and 5 nm.

8. A semiconductor structure, comprising:
a first device structure on a surface of a substrate;
a second device structure on the surface of the substrate;
a first sidewall spacer on sidewalls of the first device structure, the first sidewall spacer comprising:
a first inner liner layer on the sidewalls of the first device structure;
a first oxide spacer on the first inner liner layer and on the surface of the substrate; and
a first outer liner layer on the first oxide spacer; and
a second sidewall spacer on sidewalls of the second device structure, the second sidewall spacer comprising:
a second inner liner layer on the sidewalls of the second device structure;
an inner oxide spacer on the second inner liner layer and on the surface of the substrate;
a second outer liner layer on the inner oxide layer; and
an outer oxide spacer on the second outer liner layer,
wherein the first inner liner layer and the second inner liner layer comprise silicon-containing nitride material, and the first oxide spacer, the inner oxide spacer, and the outer oxide spacer comprise silicon-containing oxide material.

9. The semiconductor structure of claim 8, wherein the first device structure and the second device structure each comprise a gate dielectric on the surface of the substrate, a gate layer on the gate dielectric, a metal layer on the gate layer, and a cap layer on the metal layer.

10. The semiconductor structure of claim 9, wherein
the gate dielectric comprises a dielectric material having a dielectric constant greater than that of silicon dioxide,
the gate layer comprises conductively-doped silicon-containing material,
the metal layer comprises tungsten, and
the cap layer comprises silicon nitride.

11. The semiconductor structure of claim 8, wherein the substrate comprises lightly-doped regions outside of the second inner liner layer.

12. The semiconductor structure of claim 8, wherein
the first outer liner layer and the second outer liner layer comprise silicon-containing nitride material.

13. The semiconductor structure of claim 8, wherein
the first outer liner layer and the second outer liner layer comprise polycrystalline silicon.

14. The semiconductor structure of claim 8, wherein
the first sidewall spacer has a thickness of between 10 nm and 20 nm, and
the second sidewall spacer has a thickness of between 20 nm and 30 nm.

15. A method of forming a semiconductor structure, comprising:
forming a first liner layer on sidewalls of a first device structure on a surface of a substrate, and a second liner layer on sidewalls of a second device structure on the surface of the substrate;
forming a first oxide layer on the surface of the substrate, top surfaces of the first and second device structures, the first and second liner layers, and an etch stop layer on the first oxide layer;
forming a second oxide layer on a portion of the etch stop layer on the sidewalls of the first and second device structures;
removing the second oxide layer from the sidewalls of the first device structure;
removing a portion of the etch stop layer on the substrate and the top surfaces of the first and second device structures; and
removing a portion of the first oxide layer on the substrate and the top surfaces of the first and second device structures.

16. The method of claim 15, wherein the forming of the first and second liner layers comprises:
a deposition process depositing a nitride layer conformally on the surface of the substrate, and the sidewalls and the top surfaces of the first and second device structures, the nitride layer comprising silicon-containing nitride material; and
an etch process removing a portion of the deposited nitride layer on the surface of the substrate and the top surfaces of the first and second device structures.

17. The method of claim 15, wherein
forming the first oxide layer comprises forming a layer of silicon-containing oxide material, and
forming the etch stop layer comprises forming a layer of silicon-containing nitride material.

18. The method of claim 15, wherein
forming the first oxide layer comprises forming a layer of silicon-containing oxide material, and
forming the etch stop layer comprises forming a layer of polycrystalline silicon.

19. The method of claim 15, wherein the forming of the second oxide layer comprises:
a deposition process depositing an oxide layer conformally on the etch stop layer on the substrate, and the top surfaces and the sidewalls of the first and second device structures, the oxide layer comprising silicon-containing oxide material; and
an etch process removing a portion of the deposited oxide layer on the surface of the substrate and top surfaces of the first and second device structures down to the etch stop layer.

20. The method of claim 15, wherein the removing of the second oxide layer comprises:
a lithography process forming a patterned photoresist that covers the second device structure; and
an etch process removing the second oxide layer only from the sidewalls of the first device structure and leaving the second oxide layer on the sidewalls of the second device structure.
